(19) United States
(12) Patent Application Publication
(10) Pub. No.: US 2014/0159733 A1
(43) Pub. Date: Jun. 12, 2014

(54) DETECTION APPARATUS FOR LIGHT-EMITTING DIODE CHIP

(71) Applicant: GENESIS PHOTONICS INC, Tainan City (TW)

(72) Inventors: TAI-CHENG TSAI, Tainan City (TW); TAI-WEI WU, Tainan City (TW); HSIN-HUNG LIN, Tainan City (TW); PING-TSUNG TSAI, Tainan City (TW); GWO-JIUN SHEU, Tainan City (TW); SHOU-WEN HSU, Tainan City (TW); YUN-LI LI, Tainan City (TW)

(73) Assignee: GENESIS PHOTONICS INC, TAINAN CITY (TW)

(21) Appl. No.: 13/836,493

(22) Filed: Mar. 15, 2013

(30) Foreign Application Priority Data
Dec. 10, 2012 (TW) 101146325

(51) Int. Cl. G01R 31/44

(52) U.S. Cl. CPC G01R 31/44
USPC 324/414

(57) ABSTRACT

A detection apparatus for light-emitting diode chip comprising a light-collecting apparatus having an opening, a bracing component and a probing device is disclosed. The bracing component is designed to bear at least one light-emitting diode chip. The probing device comprises a power supply and at least two flexible current-transporting elements. The two ends of the current-transporting elements are respectively electrically connected to the light-emitting diode chip and the power supply to enable the light-emitting diode chip to emit light beams. Besides, the detection apparatus for light-emitting diode chip of the present invention further comprises a thimble to push the light-emitting diode chip into the inside of the light-collecting apparatus via the opening such that the light beams emitted by the light-emitting diode chip are collected by the light-collecting apparatus.

### CROSS-REFERENCE TO RELATED APPLICATION

This application claims priority from Taiwan Patent Application No. 101146325, filed on Dec. 10, 2012, the contents of which are hereby incorporated by reference in their entirety for all purposes.

### BACKGROUND OF THE INVENTION

1. Field of the Invention

The present invention relates to a detection apparatus, and more particularly, to a detection apparatus for detecting the light-emitting diode chip.

2. Description of the Related Art

Due to the technology improvements and the elevation of life quality, modern people pay more and more attention to illumination. From the ancient illumination measures of burning material, such as fire torches, vegetable oil lamps, candles, and kerosene lamps, of using electricity, such as incandescent lamps and fluorescent lamps, to the modem light-emitting diode (LED), it all shows that illumination plays an important role in people's ordinary life.

By combinating electrons and electronic holes, light-emitting diode emits light to provide illumination or alerting. Compared with the traditional light sources, the light-emitting diode has the advantages of high light-emitting efficiency, long service life, robust, fast response time, etc. In recent years, due to the great promotion of governments and the increasing scale of the light-emitting diode street lamps in cities, using light-emitting diode as the illumination source is available everywhere.

Generally, a probe device is used to test the luminous efficiency of the light-emitting diode chips. The probe device provides a power source to enable a light-emitting diode chip to emit light beams by using probe pins, and the light beams emitted by the light-emitting diode chip are then collected by a light-collecting apparatus of the probe device such that the luminous efficiency of the light-emitting diode chips could be determined by converting the light beams into a electric signal by a photoelectric conversion apparatus. However, a light leakage may be occurred because the limitation of the shape of the light-collecting apparatus such that the light-emitting diode chip could not be close to the light-collecting apparatus, so light beams emitted by the light-emitting diode chip can't be collected completely such that the accuracy of detecting the luminous efficiency of the light-emitting diode chip is influenced.

### SUMMARY OF THE INVENTION

In view of the foregoing problems of the prior arts, one of the objects of the present invention is to provide a detection apparatus for light-emitting diode chip to solve the problem that the light beams emitted by the light-emitting diode chip can't be collected completely by the light-collecting apparatus.

According to another object of the present invention, the present invention provides a detection apparatus for light-emitting diode chip to accurately detect the luminous efficiency of the light-emitting diode chip.

To fulfill the aforementioned objects, the present invention provides a detection apparatus for light-emitting diode chip, which comprises a light-collecting apparatus having an opening, a bracing component and a probing device. The bracing component is designed to bear at least one light-emitting diode chip, and the position of the light-emitting diode chip is corresponding to the opening of the light-collecting apparatus. The probing device comprises a power supply and at least two flexible current-transporting elements, and two ends of the current-transporting elements are respectively electrically connected to the light-emitting diode chip and the power supply to enable the light-emitting diode chip to emit light beams. Because the current-transporting elements are flexible such that the light-emitting diode chip and the opening of the light-collecting apparatus are more closer to each other, the light beams emitted by the light-emitting diode chip can go into the light-collecting apparatus more completely such that the problem of the light leakage between the light-collecting apparatus and the light-emitting diode chip can be solved. More clearly speaking, the current-transporting elements comprise a transparent film and a transparent conductive layer, and the transparent conductive layer is disposed on the transparent film, wherein the material of the transparent conductive layer is indium tin oxide (ITO) or indium zinc oxide (IZO), and the transparency of the transparent film is larger than 80%. The material of the transparent film is not limited to polyethylene terephthalate (PET), polyethylene (PE), polyethylene naphthalate (PEN), polyether sulfone (PES), polypropylene (PP), polybutylene terephthalate (PBT), polycarbonate (PC), polyvinyl chloride (PVC) or polystyrene (PS), wherein the material of the transparent film is preferred polyethylene terephthalate (PET), polyethylene (PE) or polyvinyl chloride (PVC). Besides, the transparent film is flexible, and the transparent conductive layer is disposed on the flexible transparent film such that the current-transporting elements with flexibility are obtained. The light-collecting apparatus can be, for example, an integral sphere, a solar panel or a photodetector array, and the solar panel or the photodetector array preferably can be an apparatus arranged in cap-shape to collect the light beams emitted by the light-emitting diode chip, wherein the photodetector array is an array of photoelectric diodes, charge coupled devices (CCDs), quantum optical detectors, photoelectric gates, light dependent resistances, phototransistors, or photoconductors, and the light-collecting apparatus is preferred an integral sphere.

Additionally, the apparatus for light-emitting diode chip of the present invention further comprises a thimble to push the light-emitting diode chip into the inside of the light-collecting apparatus via the opening such that the light beam emitted by the light-emitting diode chip are collected by the light-collecting apparatus.

According to the first preferred embodiment of the present invention, the thimble is disposed under the bracing component and the light-collecting apparatus, and the light-emitting diode chip is disposed between the current-transporting elements and the bracing component, and the current-transporting elements are disposed over the light-emitting side of the light-emitting diode chip. When the bracing component is pushed by the thimble, the light beams emitted by the light-emitting diode chip on the bracing component pass through current-transporting elements such that the light beams emitted by the light-emitting diode chip can be completely collected by the light-collecting apparatus,

According to the second preferred embodiment of the present invention, this detection apparatus is similar to the detection apparatus of the first preferred embodiment, and the difference is that the current-transporting elements of the detection apparatus of the second preferred embodiment are respectively disposed over two sides of the light-emitting diode chip. When the bracing component is pushed by the thimble, the light beams emitted by the light-emitting diode chip on the bracing component pass through current-transporting elements such that the light beams emitted by the light-emitting diode chip can be more completely collected by the light-collecting apparatus.

According to the third preferred embodiment of the present invention, this detection apparatus is similar to the detection apparatus of the first preferred embodiment, and the difference is that the current-transporting elements of the detection apparatus of the third preferred embodiment are disposed between the thimble and the bracing component. When the bracing component is pushed by the thimble, the light beams emitted by the light-emitting diode chip on the bracing component go directly into the light-collecting apparatus such that the light beams emitted by the light-emitting diode chip can be more completely collected by the light-collecting apparatus.

According to the fourth preferred embodiment of the present invention, this detection apparatus is similar to the detection apparatus of the first preferred embodiment, and the difference is that the thimble is disposed above the bracing component and the light-collecting apparatus, and the current-transporting elements are disposed between the bracing component and the light-emitting diode chip. The bracing component of the fourth preferred embodiment is constituted by a transparent material with transparency larger than 80%, and the bracing component is elastic. When the light-emitting diode chip is pushed by the thimble, the light beams emitted by the light-emitting diode chip pass through the current-transporting merits and the bracing component such that the light beams emitted by the light-emitting diode chip can be more completely collected by the light-collecting apparatus.

According to the fifth preferred embodiment of the present invention, this detection apparatus is similar to the detection apparatus of the fourth preferred embodiment, and the difference is that the current-transporting elements of the detection apparatus of the fifth preferred embodiment are respectively disposed over two sides of the light-emitting diode chip. When the light-emitting diode chip is pushed by the thimble, the light beams emitted by the light-emitting diode chip pass through current-transporting elements and the bracing component such that the light beams emitted by the light-emitting diode chip can be more completely collected by the light-collecting apparatus.

According to the sixth preferred embodiment of the present invention, this detection apparatus is similar to the detection apparatus of the fourth preferred embodiment, and the difference is that the current-transporting elements of the detection apparatus of the sixth preferred embodiment are disposed between the thimble and the light-emitting diode chip. When the light-emitting diode chip is pushed by the thimble, the light beams emitted by the light-emitting diode chip pass through the bracing component such that the light beams emitted by the light-emitting diode chip can be more completely collected by the light-collecting apparatus.

As above-mentioned, the detection apparatus for light-emitting diode chip of the present invention may have one or more characteristics and advantages as described below:

(1) In the detection apparatus for light-emitting diode chip of the present invention, the light-collecting apparatus can be more closer to the light-emitting diode chip by the flexible current-transporting dements such that the light beams emitted by the light-emitting diode chip can enter the light-collecting apparatus more completely to solve the problem of the light leakage between the light-collecting apparatus and the light-emitting diode chip.

(2) In the detection apparatus for light-emitting diode chip of the present invention, the problem that the light beams emitted by the light-emitting diode chip can't be collected completely by the light-collecting apparatus can be solved by pushing the light-emitting diode chip into the light-collecting apparatus by using the thimble.

(3) In the detection apparatus for light-emitting diode chip of the present invention, the problem that the light beams emitted by the light-emitting diode chip can't be collected completely by the light-collecting apparatus can be solved by pushing the light-emitting diode chip into the light-collecting apparatus by using the thimble, so the luminous efficiency of the light-emitting diode chip can be detected accurately.

### BRIEF DESCRIPTION OF THE DRAWINGS

FIG. 1 is a schematic sectional view showing a detection apparatus for a light-emitting diode chip of the present invention;

FIG. 2 is a schematic sectional view showing the detection apparatus for the light-emitting diode chip according to a first preferred embodiment of the present invention;

FIG. 3 is a schematic sectional view showing the light-emitting diode chip pushing into the integral sphere by using the thimble of the first preferred embodiment of the present invention;

FIG. 4 is a schematic sectional view showing the detection apparatus for the light-emitting diode chip according to a second preferred embodiment of the present invention;

FIG. 5 is a schematic sectional view showing the detection apparatus for the light-emitting diode chip according to a third preferred embodiment of the present invention;

FIG. 6 is a schematic sectional view showing the detection apparatus for the light-emitting diode chip according to a fourth preferred embodiment of the present invention;

FIG. 7 is a schematic sectional view showing the detection apparatus for the light-emitting diode chip according to a fifth preferred embodiment of the present invention; and

FIG. 8 is a schematic sectional view showing the detection apparatus for the light-emitting diode chip according to the sixth preferred embodiment of the present invention.

### DETAILED DESCRIPTION OF THE PREFERRED EMBODIMENTS

In the detection apparatus for light-emitting diode chip of the present invention, the traditional probe pins are replaced by the flexible current-transporting elements such that the light beams emitted by the light-emitting diode chip can be collected completely by the light-collecting apparatus to achieve the purpose of detecting the luminous efficiency of the light-emitting diode chip accurately. The light-collecting apparatus can be an integral sphere, a solar panel or a photodetector array, wherein the photodetector array is an array of photoelectric diodes, charge coupled devices (CCDs), quantum optical detectors, photoelectric gates, light dependent resistances, phototransistors, or photoconductors. Wherein, the light-collecting apparatus is preferred an integral sphere. The several embodiments of the detection apparatus for light-emitting diode chip of the present invention will be listed below to illustrate the detection apparatus for light-emitting diode chip of the present invention, and these embodiments are not limited to the present invention.

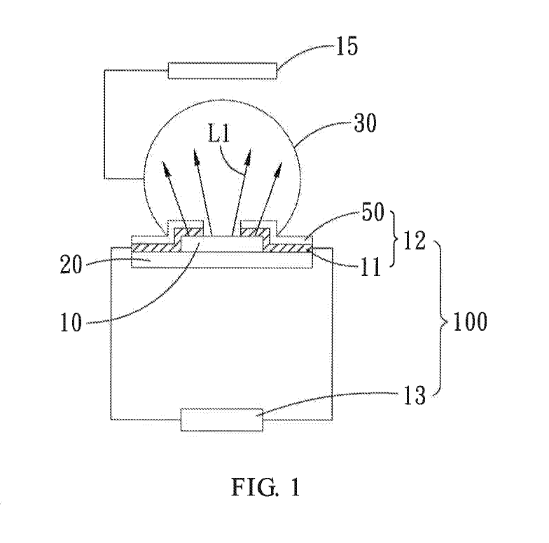

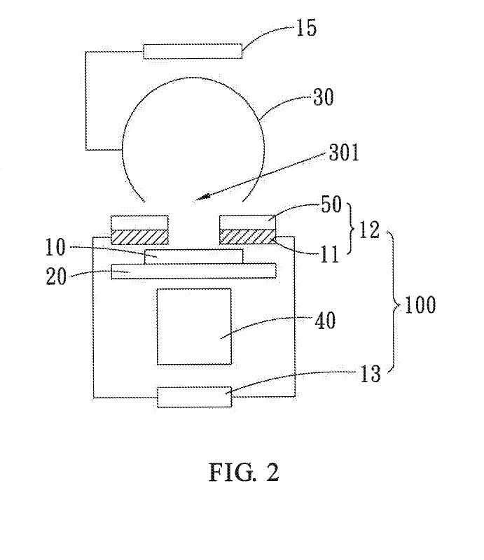

Referring to FIG. 1, which is a schematic sectional view showing a detection apparatus for a light-emitting diode chip of the present invention. The detection apparatus of the present invention comprises an integral sphere 30 having an opening 301, a bracing component 20 and a probing device 100 (the position of the opening 301 referring to FIG. 2), The bracing component 20 is designed to bear at least one light-emitting diode chip 10, and the position of the light-emitting diode chip 10 to be detected is corresponding to the opening 301 of the integral sphere 30. The probing device 100 comprises a power supply 13 and at least two flexible current-transporting elements 12, and two ends of the current-transporting elements 12 are respectively electrically connected to the light-emitting diode chip 10 and the power supply 13 to enable the light-emitting diode chip 10 to emit light beams L1. Because the current-transporting elements are flexible such that the light-emitting diode chip and the opening of the integral sphere are more closer to each other, the light beams emitted by the light-emitting diode chip can go into the light-collecting apparatus more completely such that the problem of the light leakage between the light-collecting apparatus and the light-emitting diode chip can be solved.

Referring to FIG. 2 and FIGS. 4-8, which are schematic sectional views showing the detection apparatus for the light-emitting diode chip according to the first preferred embodiment to the sixth preferred embodiment of the present invention. However, any modification of the embodiments under the scope of the invention is within the protection scope of the present invention.

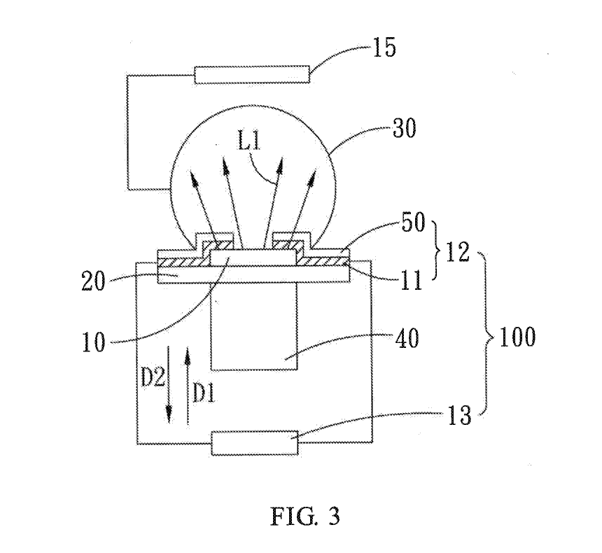

Referring to both FIG. 2 and FIG. 3, wherein FIG. 3 is a schematic sectional view showing the light-emitting diode chip pushed into the integral sphere by using the thimble of the first preferred embodiment of the present invention. As shown in FIG. 2 and FIG. 3, the first embodiment of the present invention comprises an integral sphere 30 having an opening 301, a bracing component 20, a thimble 40 and a probing device 100. The bracing component 20 is designed to bear at least one light-emitting diode chip 10, and the thimble 40 is disposed under the bracing component 20 and the integral sphere 30, and the location of the light-emitting diode chip 10 to be detected is corresponding to the opening 301 of the integral sphere 30. The probing device 100 comprises a power supply 13 and at least two flexible current-transporting elements 12, and two ends of the current-transporting elements 12 are respectively electrically connected to the light-emitting diode chip 10 and the power supply 13 to enable the light-emitting diode chip 10 to emit light beams L1. The thimble 40 is designed to push the light-emitting diode chip 10 along the direction D1 into the inside of the integral sphere 30 via the opening 301 such that the light beams L1 are collected by the integral sphere 30 and the light beams L1 are converted into an electric signal by the photoelectric conversion apparatus 15. Wherein, the current-transporting elements 12 comprises a transparent conductive layer 11 and a transparent film 50, wherein the material of the transparent conductive layer 11 is a material with transparent property such as indium tin oxide or indium zinc oxide, and the material of the transparent film 50 is polyethylene terephthalate, polyethylene or polyvinyl chloride, and the transparency thereof is larger than 80%, and the transparent film 50 is flexible. Wherein, the transparent film 50 is preferred polyvinyl chloride.

In the first preferred embodiment of the present invention, the light-emitting diode chip 10 is disposed between the current-transporting elements 12 and the bracing component 20, and the two current-transporting elements 12 are both disposed over the light-emitting side of the light-emitting diode chip 10. Beside, each of the current-transporting elements 12 is electrically insulated from the other current-transporting elements 12 located adjacent thereto such that different voltages can be received by the light-emitting diode chip 10 electrically connected to these two current-transporting elements 12 to enable the light-emitting diode chip 10 to emit light beams.

Referring to FIG. 3, when the bracing component 20 is pushed along the direction D1 by the thimble 40 such that the light-emitting diode chip 10 on the bracing component 20 electrically connects to the current-transporting elements 12, the light-emitting diode chip 10 along with the current-transporting elements 12 can be pushed into the inside of the integral sphere 30 along the direction D1 by the thimble 40 because the current-transporting elements 12 are flexible, and a voltage difference can be provided by the current-transporting elements 12 next to each other to enable the light-emitting diode chip 10 to emit light beams L1. Because the light beams emitted by the light-emitting diode chip 10 can pass through the current-transporting elements 12 with the transparent property, the light beams L1 emitted by the light-emitting diode chip 10 can be more completely collected by the integral sphere 30 to achieve the purpose of detecting the luminous efficiency of the light-emitting diode chip 10 accurately.

As shown in FIG. 2 and FIG. 3, the first preferred embodiment of detection apparatus for light-emitting diode chip of the present invention is suitable for detecting the luminous efficiency of the light-emitting diode chip 10, the detection procedures are as follows: the light-emitting diode chip 10 is supported by the bracing component 20; moves the thimble 40 along the direction D1 to push the bracing component 20 such that the light-emitting diode chip 10 on the bracing component 20 electrically connects the current-transporting elements 12; then, push the light-emitting diode chip 10 along with the current-transporting elements 12 along the direction D1 into the inside of the integral sphere 30, and provides a voltage to enable the light beams L1 emitted by the light-emitting diode chip 10 pass through the current-transporting elements 12 and go forward the integral sphere 30 such that the light beams L1 can be collected more completely by the integral sphere 30; then, the light signal is received and converted into an electric signal by the photoelectric conversion apparatus 15 to show the luminous efficiency of the light-emitting diode chip 10; finally, the thimble 40 can be moved along the direction D2 such that the light-emitting diode chip 10 is away from the detection region of the integral sphere 30 to finish the detection of detecting the luminous efficiency of the light-emitting diode chip 10.

Besides, in the detection procedures of the first preferred embodiment of the present invention, the thimble 40 provides the function of pushing the light-emitting diode chip 10 into or out of the detection region of the integral sphere 30, and the term “pushing out” herein means that because the transparent film 50 of the current-transporting elements 12 is flexible, when there is no force to the bracing component 20 by the thimble 40, the light-emitting diode chip 10 and the bracing component 20 will be moved out along the direction D2 from the integral sphere 30 owing to the rebounding force of the transparent film 50. In other words, user can push the light-emitting diode chip 10 into the inside of the integral sphere 30 by the thimble 40, then apply the probing device 100 to provide a voltage source to the light-emitting diode chip 10 to achieve the purpose of collecting the light beams L1 emitted by the light-emitting diode chip 10.

In the detection apparatus for light-emitting diode chip of the present invention, the position of the current-transporting elements 12 are not limited to any foregoing embodiment of the present invention, any position of the current-transporting elements 12 providing the light-emitting diode chip with a voltage such that the light beams can be emitted by the light-emitting diode chip is within the protection scope of the present invention.

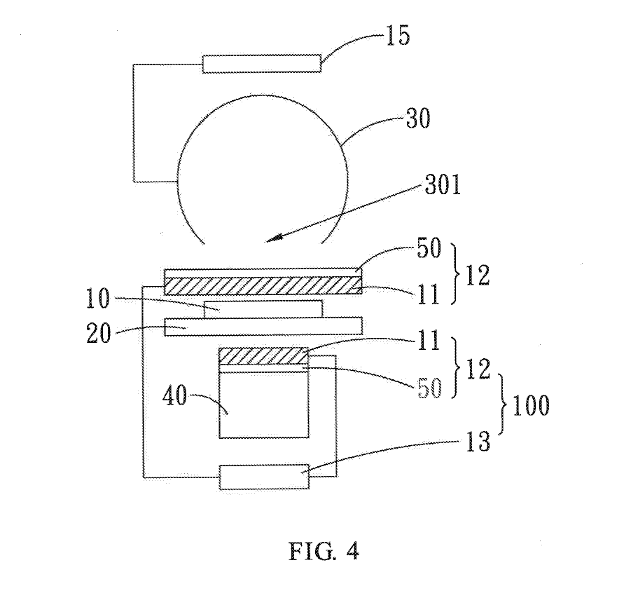

Referring to FIG. 4, which is a schematic sectional view showing the detection apparatus for the light-emitting diode chip according to the second preferred embodiment of the present invention. In the second preferred embodiment of the present invention, the current-transporting elements 12 are respectively disposed over two sides of the light-emitting diode chip 10, wherein one current-transporting element 12 is disposed over the light-emitting surface of the light-emitting diode chip 10, and the other current-transporting element 12 is disposed between the thimble 40 and the bracing component 20 to supply the voltage source to the light-emitting diode chip 10 supported on the bracing component 20. Thus, in the second preferred embodiment of the present invention, the material of the bracing component 20 must be a material with conductive property to achieve the function of providing voltage to the light-emitting diode chip 10. Wherein, the current-transporting elements 12 comprises a transparent conductive layer 11 and a transparent film 50, wherein the material of the transparent conductive layer 11 is a material with transparent property such as indium tin oxide or indium zinc oxide, and the material of the transparent film 50 is polyethylene terephthalate, polyethylene or polyvinyl chloride, and the transparency thereof is larger than 80%, and the transparent film 50 is flexible. Wherein, the transparent film 50 is preferred polyvinyl chloride.

As shown in FIG. 4 and FIG. 2, the difference between the second preferred embodiment and the first preferred embodiment of the present invention is that the current-transporting elements 12 of the second preferred embodiment are respectively disposed over two sides of the light-emitting diode chip 10, wherein one current-transporting element 12 is disposed over the light-emitting surface of the light-emitting diode chip 10, and the other current-transporting element 12 is disposed between the thimble 40 and the bracing component 20. The detection procedures of the second preferred embodiment of the present invention are as follows: the light-emitting diode chip 10 is supported by the bracing component 20; the bracing component 20 is pushed by moving the thimble 40, then, the light-emitting diode chip 10 along with the current-transporting element 12 are pushed along the direction D1 into the inside of the integral sphere 30, applying a voltage such that the light-emitting diode chip 10 electrically connected to the current-transporting element 12 respectively disposed on the light-emitting surface thereof and the thimble 40 emits light beams L1; the light beams L1 pass through the current-transporting element 12 and go forward the integral sphere 30 to enable the light beams L1 to be collected more completely by the integral sphere 30 and converted the light beams L1 emitted by the light-emitting diode chip 10 into an electric signal by the photoelectric conversion apparatus 15 such that the luminous efficiency of the light-emitting diode chip 10 is displayed by the photoelectric conversion apparatus 15.

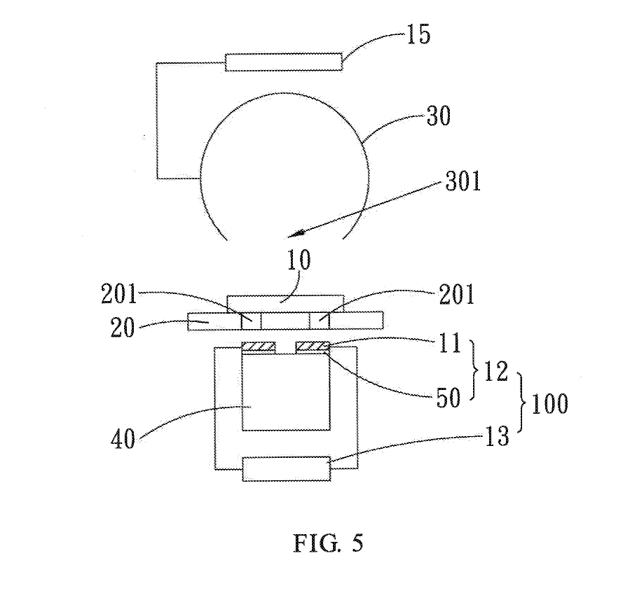

Beside, in the detection apparatus for light-emitting diode chip of the present invention, user can dispose the current-transporting element 12 on the thimble 40 directly for practical demand. As shown in FIG. 5, it is a schematic sectional view showing the detection apparatus for the light-emitting diode chip according to the third preferred embodiment of the present invention. In the third embodiment of the present invention, the current-transporting elements 12 are disposed on the surface of the thimble 40 to supply the voltage source to the light-emitting diode chip 10 on the bracing component 20. Besides, because the voltage source is provided by the current-transporting element 12 on the surface of the thimble 40 to enable the light-emitting diode chip 10 to emit light beams, in the third embodiment of the present invention, the conductive regions 201 must be disposed in the bracing component 20 respectively corresponding to the positions of the two current-transporting elements 12 such that when the thimble 40 contacts the bracing component 20, the light-emitting diode chip 10 can be electrically connected by the conductive regions 201, and the light-emitting diode chip 10 can be pushed into the inside of the integral sphere 30 along with the current-transporting element 12 and enable the light-emitting diode chip 10 to emit light beams L1. Wherein, the current-transporting element 12 comprises a transparent conductive layer 11 and a transparent film 50, and the material of the transparent conductive layer 11 can be, for example, indium tin oxide or indium zinc oxide, but not limited thereto.

As shown in FIG. 5 and FIG. 2, the difference between the third preferred embodiment and the first preferred embodiment of the present invention is that the current-transporting elements 12 of the third preferred embodiment are disposed between the thimble 40 and the bracing component 20. The detection procedures of the third preferred embodiment of the present invention are as follows: the light-emitting diode chip 10 is supported by the bracing component 20; the bracing component 20 is pushed by moving the thimble 40 until the bracing component 20 was pushed into, the inside of the integral sphere 30 such that the light-emitting diode chip 10 emits the light beams L1 by the conductive regions 201 electrically connecting to the current-transporting elements 12 disposed on the thimble 40; the light beams L1 are collected by the integral sphere 30 and converted into an electric signal by the photoelectric conversion apparatus 15 such that the luminous efficiency of the light-emitting diode chip 10 is displayed by the photoelectric conversion apparatus 15.

The detection apparatus for light-emitting diode chip of the present invention has the flexible current-transporting elements and the thimble, and the purpose of accurately detecting the luminous efficiency of the light-emitting diode chip can be achieved by pushing the light-emitting diode chip into the inside of the integral sphere such that the light beams emitted by the light-emitting diode chip can be collected more completely by the integral sphere. However, in the detection apparatus for light-emitting diode chip of the present invention, the detection apparatus for light-emitting diode chip of the present invention is not limited to the figures of the first to third preferred embodiments mentioned above. The detection apparatus for light-emitting diode chip of the present invention further can be the fourth to sixth preferred embodiments below.

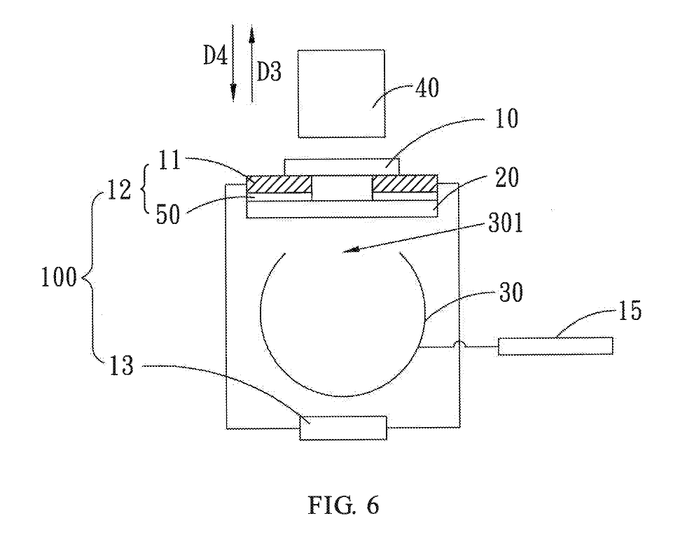

FIG. 6 to FIG. 8 are schematic sectional views showing the detection apparatus for the light-emitting diode chip according to the fourth to sixth preferred embodiments of the present invention. In the fourth to sixth preferred embodiments of the present invention, the thimble 40 is disposed above the bracing component 20 and the integral sphere 30, and the bracing component 20 is constituted by a material with transparency lager than 80% and flexible property. When the light-emitting diode chip 10 along with the bracing component 20 are pushed into the inside of the integral sphere 30 by the thimble 40, the light beams L1 emitted by the light-emitting diode chip 10 pass through the bracing component 20 with transparent property such that the light beams L1 emitted by the light-emitting diode chip 10 can be more completely collected by the integral sphere 30.

Referring to FIG. 6, in the fourth embodiment of the present invention, the current-transporting elements 12 are disposed between the light-emitting diode chip 10 and the bracing component 20, and each of the current-transporting elements 12 is electrically insulated from the other current-transporting elements 12 located adjacent thereto such that different voltages can be received by the light-emitting diode chip 10 electrically connected to these two current-transporting elements 12 such that the light-emitting diode chip 10 can emit light beams. Wherein, the current-transporting element 12 comprises a transparent conductive layer 11 and a transparent film 50, and the material of the transparent conductive layer 11 can be, for example, indium tin oxide or indium zinc oxide.

As shown in FIG. 6 and FIG. 2, the difference between the fourth preferred embodiment and the first preferred embodiment of the present invention is that the thimble 40 of the fourth preferred embodiment is disposed above the bracing component 20 and the integral sphere 30, and the current-transporting elements 12 are disposed between the light-emitting diode chip 10 and the bracing component 20. The thimble 40 is directly connected to the light-emitting diode chip 10 and pushed along the direction D4 into the inside of the integral sphere 30 via the opening 301. The detection procedures of the fourth preferred embodiment of the present invention are as follows: the light-emitting diode chip 10 is supported by the bracing component 20 with two current-transporting elements 12; the light-emitting diode chip 10 is pushed by moving the thimble 40 along the direction D4 such that the light-emitting diode chip 10 along with the bracing component 20 are pushed into the inside of the integral sphere 30 by the thimble 40; and a detection process is performed by the probing device 100, wherein the power supply 13 of the probing device 100 provides a voltage source to the light-emitting diode chip 10 by using the current-transporting elements 12 to enable the light-emitting diode chip 10 to emit the light beams L1; the light beams L1 emitted by the light-emitting diode chip 10 are collected by the integral sphere 30 and converted into an electric signal by the photoelectric conversion apparatus 15 such that the luminous efficiency of the light-emitting diode chip 10 is displayed by the photoelectric conversion apparatus 15; finally, the thimble 40 can be moved along the direction D3 such that the light-emitting diode chip 10 is away from the detection region of the integral sphere 30 to finish the detection of detecting the luminous efficiency of the light-emitting diode chip 10.

Compared to the fourth preferred embodiment, in the detection apparatus for light-emitting diode chip of the present invention, the current-transporting elements 12 can be disposed between the light-emitting diode chip 10 and the bracing component 20 (as illustrated in FIG. 6 and the fourth preferred embodiment), and user can dispose the current-transporting elements 12 on the other elements of the detection apparatus of the present invention. And, the positions of the current-transporting elements 12 are not limited to any foregoing embodiment of the present invention, any position of the current-transporting elements 12 providing the light-emitting diode chip with a voltage such that the light beams can be emitted by the light-emitting diode chip is within the protection scope of the present invention.

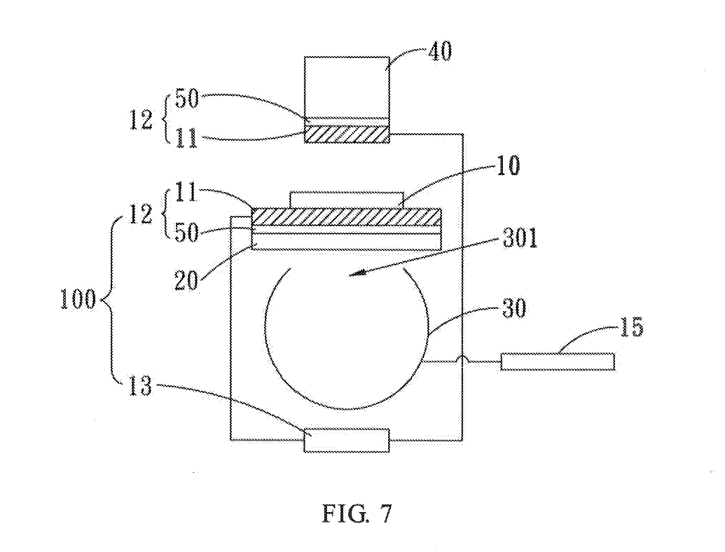

Referring to FIG. 7, which is a schematic sectional view showing the detection apparatus for the light-emitting diode chip according to the fifth preferred embodiment of the present invention. In the fifth embodiment of the present invention, the bracing component 20 is flexible and constituted by a transparent material with transparency lager than 80%, and the current-transporting elements 12 are respectively disposed over two sides of the light-emitting diode chip 10 to supply the voltage source to the light-emitting diode chip 10. When the light-emitting diode chip 10 is pushed by the thimble 40, the bracing component 20 can be pushed into the inside of the integral sphere 30, and the light beams L1 emitted by the light-emitting diode chip 10 pass through the bracing component 20 with transparent property such that the light beams L1 emitted by the light-emitting diode chip 10 can be more completely collected by the integral sphere 30. Wherein, the current-transporting element 12 disposed on the bracing component 20 comprises a transparent conductive layer 11 and a transparent film 50, and the material of the transparent conductive layer 11 can be, for example, indium tin oxide or indium zinc oxide.

As shown in FIG. 7 and FIG. 6, the difference between the fifth preferred embodiment and the fourth preferred embodiment of the present invention is that the current-transporting elements 12 of the fifth preferred embodiment are respectively disposed over two sides of the light-emitting diode chip 10. The detection procedures of the fifth preferred embodiment of the present invention are as follows: the light-emitting diode chip 10 is disposed on the bracing component 20 with a current-transporting element 12; the light-emitting diode chip 10 is electrically connected to the current-transporting element 12 respectively disposed on the thimble 40 and the bracing component 20 by moving the thimble 40; then, the light-emitting diode chip 10 along with the bracing component 20 are pushed into the inside of the integral sphere 30 to enable the light-emitting diode chip 10 to emit light beams L1, and the light beams L1 pass through the bracing component 20 and the current-transporting element 12 on the bracing component 20 and go forward the integral sphere 30 to enable the light beams L1 to be collected more completely by the integral sphere 30 and the light beams L1 emitted by the light-emitting diode chip 10 are converted into an electric signal by the photoelectric conversion apparatus 15 such that the luminous efficiency of the light-emitting diode chip 10 is displayed by the photoelectric conversion apparatus 15.

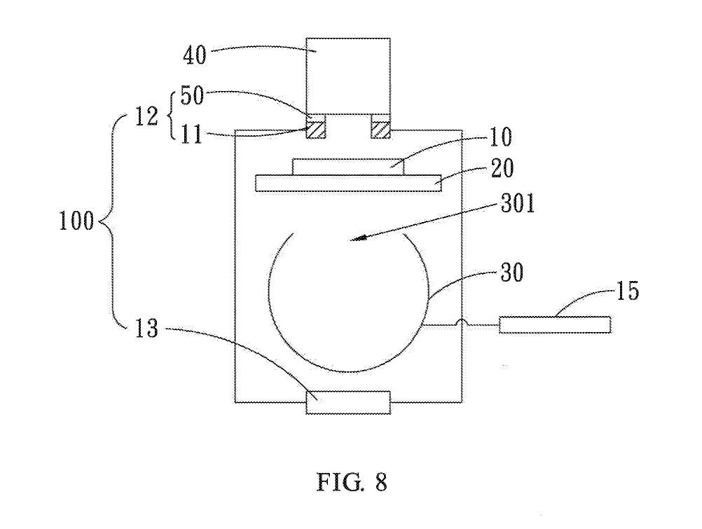

Besides, in the detection apparatus for light-emitting diode chip of the present invention, user can dispose the current-transporting element 12 between the thimble 40 and the light-emitting diode chip 10 for practical demand. As shown in FIG. 8, it is a schematic sectional view showing the detection apparatus for the light-emitting diode chip according to the sixth preferred embodiment of the present invention. In the sixth embodiment of the present invention, the bracing component 20 is constituted by a transparent material with transparency lager than 80% and flexible property, and the current-transporting element 12 are disposed between the thimble 40 and the light-emitting diode chip 10 to supply the voltage source to the light-emitting diode chip 10 on the bracing component 20.

As shown in FIG. 8 and FIG. 6, the difference between the sixth preferred embodiment and the fourth preferred embodiment of the present invention is that the current-transporting elements 12 of the sixth preferred embodiment are disposed between the thimble 40 and the light-emitting diode chip 10. The detection procedures of the sixth preferred embodiment of the present invention are as follows: the light-emitting diode chip 10 is supported on the bracing component 20; the light-emitting diode chip 10 is electrically connected to the current-transporting element 12 disposed between the thimble 40 and the light-emitting diode chip 10 by moving the thimble 40; keep pushing the thimble 40 such that the light-emitting diode chip 10 along with the bracing component 20 are pushed into the inside of the integral sphere 30 and emits light beams L1 to enable the light beams L1 to be collected more completely by the integral sphere 30 and the light beams L1 are converted into an electric signal by the photoelectric conversion apparatus 15 such that the luminous efficiency of the light-emitting diode chip 10 is displayed by the photoelectric conversion apparatus 15.

In summary, the detection apparatus for light-emitting diode chip of the present invention utilizes a thimble to push the light-emitting diode chip into the inside of the integral sphere such that the light beams emitted by the light-emitting diode chip can be collected completely by the integral sphere to achieve the purpose of detecting the luminous efficiency of the light-emitting diode chip accurately.

In summation, although the present invention has been described with reference to the foregoing preferred embodiment, it will be understood that the invention is not limited to the details thereof. Various equivalent variations and modifications may still occur to those skilled in this art in view of the teachings of the present invention. Thus, all such variations and equivalent modifications are also embraced within the scope of the invention as defined in the appended claims.

What is claimed is:

1. A detection apparatus for light-emitting diode chip, comprising:
a light-collecting apparatus having an opening;
a bracing component to bear at least one light-emitting diode chip; and
a probing device, comprising a power supply and at least two flexible current-transporting elements each having two ends respectively electrically connected to the light-emitting diode chip and the power supply to enable the light-emitting diode chip to emit light beams.

2. The detection apparatus for light-emitting diode chip of claim 1, wherein current-transporting elements comprise a transparent film and a transparent conductive layer, and the transparent conductive layer is disposed on the transparent film.

3. The detection apparatus for light-emitting diode chip of claim 2, wherein the material of the transparent conductive layer is indium tin oxide (ITO) or indium zinc oxide (IZO).

4. The detection apparatus for light-emitting diode chip of claim 2, wherein the material of the transparent film is polyethylene terephthalate, polyvinyl chloride or polyethylene.

5. The detection apparatus for light-emitting diode chip of claim 1, wherein the light-collecting apparatus is an integral sphere, a solar panel or a photodetector array.

6. The detection apparatus for light-emitting diode chip of claim 1, further comprising a thimble, and the thimble is disposed under the bracing component and the light-collecting apparatus to push the light-emitting diode chip into the inside of the light-collecting apparatus via the opening such that the light beams emitted by the light-emitting diode chip are collected by the light collecting apparatus.

7. The detection apparatus for light-emitting diode chip of claim 6, wherein the light-emitting diode chip is disposed between the current-transporting elements and the bracing component.

8. The detection apparatus for light-emitting diode chip of claim 6, wherein the current-transporting elements are respectively disposed over two sides of the light-emitting diode chip.

9. The detection apparatus for light-emitting diode chip of claim 6, wherein the current-transporting elements are disposed between the thimble and the bracing component.

10. The detection apparatus for light-emitting diode chip of claim 1, further comprising a thimble, and the thimble is disposed above the bracing component and the light-collecting apparatus to push the light-emitting diode chip into the inside of the light collecting apparatus via the opening such that the light beams emitted by the light-emitting diode chip are collected by the light collecting apparatus, and the bracing component is constituted by a transparent material with transparency larger than 80%.

11. The detection apparatus for light-emitting diode chip of claim 10, wherein the current-transporting elements are disposed between the bracing component and the light-emitting diode chip.

12. The detection apparatus for light-emitting diode chip of claim 10, wherein the current-transporting elements are respectively disposed over two sides of the light-emitting diode chip.

13. The detection apparatus for light-emitting diode chip of claim 10, wherein the current-transporting elements are disposed between the thimble and the light-emitting diode chip.
